(19) United States
(12) Patent Application Publication
(10) Pub. No.: US 2006/0175640 A1
(43) Pub. Date: Aug. 10, 2006

(54) Semiconductor memory device, memory cell array, and method for fabricating the same

(76) Inventors: Thomas Happ, Tarrytown, NY (US); Cay-Uwe Pinnow, Corbeil-Essonnes (FR); Ulrike Gruning Von Schwerin, Munchen (DE)

Correspondence Address: EDELL, SHAPIRO & FINNAN, LLC, 1901 RESEARCH BLVD., SUITE 400, ROCKVILLE, MD, 20850, US

(21) Appl. No.: 11/329,420

(22) Filed: Jan. 11, 2006

(30) Foreign Application Priority Data
Jan. 11, 2005 (DE) 10 2005 001 253.1

(51) Int. Cl. H01L 29/76

(52) U.S. Cl. 257/288

(57) ABSTRACT

A semiconductor memory device suitable for use in a memory cell array includes a solid electrolyte memory cell including: a first electrode device, a second electrode device, and a solid electrolyte material region between the first and second electrode devices. The solid electrolyte material region is materially cohesive, and the second electrode device is materially cohesive.

### CROSS REFERENCE TO RELATED APPLICATIONS

This application claims priority under 35 USC § 119 to German Application No. DE 10 2005 001 253.1, filed on Jan. 11, 2005, and titled “Memory Cell Array, Method for Fabricating it and Semiconductor Memory Device,” the entire contents of which are hereby incorporated by reference.

### FIELD OF THE INVENTION

The present invention relates to a semiconductor memory device, a memory cell array employing such memory devices, and methods of fabricating the same.

### BACKGROUND

During the ongoing development of modern memory technologies, memory concepts which are based on the principle of resistively switching memory elements have been developed. The overall conductivity thereof can be modulated by a specific activating species, e.g., metal ions being introduced or displaced in a controlled way by an external voltage in a solid electrolyte, with corresponding memory states then being assigned to the respective total conductivities or conductivity states.

A problem with solid electrolyte memory cells based on an ion conduction mechanism of this type is that hitherto they have been difficult to integrate in standard technology concepts as are used in conventional memory cell arrays.

### SUMMARY

The invention provides a memory cell array comprising a plurality of solid electrolyte memory cells, in which each solid electrolyte memory cell is formed with a first electrode device, a second electrode device and with an activated or activatable solid electrolyte material region provided between the two electrode devices, as a memory material region, in which the solid electrolyte material region is formed in such a way as to be materially integral or cohesive, and in which the second electrode device is formed in such a way as to be materially integral.

Therefore, it is a core concept of the present invention, in a memory cell array comprising a plurality of solid electrolyte memory cells, for the solid electrolyte material regions of the solid electrolyte memory cells to be designed in such a way as to be materially integral or cohesive. Another core aspect of the present invention is for the second electrode devices of the solid electrolyte memory cells to be designed in such a way as to be materially cohesive. These measures make critical patterning processes for each individual solid electrolyte memory cell obsolete. This simplifies both the structure and corresponding fabrication methods, resulting in better integration of the memory cell array, according to the invention, to that of conventional technologies of corresponding fabrication methods.

In a preferred embodiment of the memory cell array according to the invention, it is proposed that all the solid electrolyte material regions for all the solid electrolyte memory cells of the plurality of solid electrolyte memory cells be formed as one common material layer.

In another preferred embodiment of the memory cell array according to the invention, it is proposed as an alternative or in addition that all the second (upper) electrode devices be formed as one common material layer.

It is advantageous if, according to a further embodiment of the memory cell array according to the invention, as an alternative or in addition that the first electrode device, the solid electrolyte material region and the second electrode device of a respective solid electrolyte memory cell are formed as a vertically running sequence of corresponding material regions or material layers.

It is preferable if, according to a further embodiment of the memory cell array according to the invention, as an alternative or in addition, the first electrode device is designed as an anode or as a cathode.

It is also conceivable that, according to another embodiment of the memory cell array according to the invention, as an alternative or in addition, the second electrode device be designed as a cathode or as an anode.

According to another embodiment of the memory cell array according to the invention, as an alternative or in addition, all the second electrode devices may be formed in one common vertical plane.

It is advantageous if, according to another embodiment of the memory cell array according to the invention, as an alternative or in addition all the solid electrolyte material regions are formed in one common vertical plane.

According to another embodiment of the memory cell array according to the invention, as an alternative or in addition it may furthermore be advantageous if all the first electrode devices are formed in one common vertical plane.

Furthermore, it is conceivable if, according to a further advantageous embodiment of the memory cell array according to the invention, as an alternative or in addition, the first electrode device is formed so as to comprise or consist of one or more of the following materials: polysilicon, tungsten, titanium, tantalum, silver, copper, and aluminum as well as one or more of the following electrically conductive materials: nitrides, oxides, alloys, and compounds of these conductive materials.

Consideration may also be given to the possibility that, according to another embodiment of the memory cell array according to the invention, as an alternative or in addition, the second electrode device is formed so as to comprise or consist of one or more of the following materials: polysilicon, tungsten, titanium, tantalum, silver, silver chalcogenides, copper and aluminum as well as one or more of the following electrically conductive materials: nitrides, oxides, alloys, and compounds of these conductive materials.

It is also preferred that, according to another embodiment of the memory cell array according to the invention, as an alternative or in addition, the solid electrolyte material region is formed so as to comprise or consist of one or more of the following materials: WOx, GeSe, GeS, SiSe, SiS, SiGe, SeS, Si—Se—S, Si—Ge—Se, Si—Ge—S, Ge—Se—S, Si—Ge—Se—S, and other chalcogenide materials.

Furthermore, the memory cell array, according to another embodiment of the memory cell array according to the invention, may as an alternative or in addition be formed on or in a semiconductor material region as substrate or on or in the surface region thereof.

According to another preferred embodiment of the memory cell array according to the invention, each solid electrolyte memory cell is as an alternative or in addition designed with an individual selection transistor.

According to another preferred embodiment of the memory cell array according to the invention, as an alternative or in addition the respective solid electrolyte material region is designed to be embedded by diffusion barriers.

In this context, it is additionally possible to provide that all corresponding diffusion barriers are formed as materially cohesive regions, and in particular as common layers.

Another aspect of the present invention also provides a semiconductor memory device comprising a memory cell array according to the invention, in particular in combination with logic circuits and switching elements and/or in the form of a processor chip.

Another aspect of the present invention also provides a method for fabricating a memory cell array comprising a plurality of solid electrolyte memory cells, in which each solid electrolyte memory cell is formed with a first (or lower) electrode device, a second (or upper) electrode device and with an activated or activatable solid electrolyte material region provided between the two electrode devices, as memory material region, in which the solid electrolyte material region is formed in such a way as to be materially cohesive, and in which the second electrode device is formed in such a way as to be materially cohesive.

In a preferred embodiment of the method according to the invention for fabricating a memory cell array comprising a plurality of solid electrolyte memory cells, all the solid electrolyte material regions are formed as one common material layer.

As an alternative or in addition, in another preferred embodiment of the method according to the invention for fabricating a memory cell array comprising a plurality of solid electrolyte memory cells, it is provided that all the second electrode devices are formed as one common material layer.

According to another advantageous embodiment of the method according to the invention for fabricating a memory cell array comprising a plurality of solid electrolyte memory cells, it is also conceivable that the first electrode device, the solid electrolyte material region and the second electrode device are formed as a vertically running sequence of corresponding material regions or material layers.

Furthermore, according to another advantageous embodiment of the method according to the invention for fabricating a memory cell array comprising a plurality of solid electrolyte memory cells, it is possible to provide, as an alternative or in addition, that the first electrode device is designed as an anode or as a cathode.

As an alternative or in addition, in another preferred embodiment of the method according to the invention for fabricating a memory cell array comprising a plurality of solid electrolyte memory cells, it is provided that the second electrode device is designed as a cathode or as an anode.

Furthermore, as an alternative or in addition, in a further preferred embodiment of the method according to the invention for fabricating a memory cell array comprising a plurality of solid electrolyte memory cells, it is provided that all the second electrode devices are formed in one common vertical plane.

According to another advantageous embodiment of the method according to the invention for fabricating a memory cell array comprising a plurality of solid electrolyte memory cells, it is in addition or as an alternative also conceivable that all the solid electrolyte material regions are formed in one common vertical plane.

It is also possible to provide that according to another embodiment of the method according to the invention for fabricating a memory cell array comprising a plurality of solid electrolyte memory cells all the first electrode devices are formed in one common vertical plane.

As an alternative or in addition, in another preferred embodiment of the method according to the invention for fabricating a memory cell array comprising a plurality of solid electrolyte memory cells, it is possible to provide that the first electrode device is formed so as to comprise or consist of one or more of the following materials: polysilicon, tungsten, titanium, tantalum, silver, copper and aluminum as well as one or more of the following electrically conductive materials: nitrides, oxides, and alloys.

Furthermore, as an alternative or in addition, it is possible to provide, in another embodiment of the method according to the invention for fabricating a memory cell array comprising a plurality of solid electrolyte memory cells, that the second electrode device is formed so as to comprise or consist of one or more of the following materials: polysilicon, tungsten, titanium, tantalum, silver, silver chalcogenides, copper and aluminum as well as one of more of the following electrically conductive materials: nitrides, oxides, and alloys.

As an alternative or in addition, in another advantageous embodiment of the method according to the invention for fabricating a memory cell array comprising a plurality of solid electrolyte memory cells, it is also possible to provide that the solid electrolyte material region is formed so as to comprise or consist of one or more of the following materials: WOx, GeSe, GeS, SiSe, SiS, SiGe, SeS, Si—Se—S, Si—Ge—Se, Si—Ge—S, Ge—Se—S, Si—Ge—Se—S and other chalcogenide materials.

It is advantageously possible to provide that the memory cell array is formed on or in a semiconductor material region as substrate or on or in the surface region thereof.

It is preferable if each solid electrolyte memory cell is designed with an individual select transistor.

Furthermore, as an alternative or in addition, it is particularly advantageous if, in another preferred embodiment of the method according to the invention for fabricating a memory cell array comprising a plurality of solid electrolyte memory cells, the solid electrolyte material region is in each case embedded by means of diffusion barriers.

In this context, it may additionally be particularly advantageous if all corresponding diffusion barriers are in each case formed as materially cohesive regions, and in particular as common layers.

These and further aspects of the present invention are explained in more detail below:

The invention in particular also relates to the integration of 1T1R-CBRAM memories with a continuous cell region.

Conductive bridging memory cells, CB memory cells or solid electrolyte memory cells, typically comprising an anode A, an ion conductor I and a cathode K or multi-layer arrangements. They represent a resistively switching element, the total conductivity of which can be assigned to a memory state. To detect the state of the cell—a logic 1 or a logic 0—the current when a read voltage U_{read} is applied is measured and evaluated.

With a solid electrolyte cell of this type, it is possible to allow metallic ions to diffuse in a controlled way through the ion conductor I, which generally has a poor electrical conductivity, by applying bipolar voltage pulses. In the simplest possible scenario, these metallic ions are identical to those of the anode material, i.e., metallic anode material is oxidized and on application of a positive write voltage U_{write}>U_{read} passes into the ion conductor I, where it is dissolved. The ion diffusion can be controlled by the duration, amplitude and/or polarity of the electrical voltage which is externally imposed on the cell. When a positive electric voltage U_{write} is applied to the solid electrolyte cell described here, the metallic cations, under the influence of the external electrical field, diffuse through the ion conductor I in the direction of the cathode K. As soon as a sufficient number of metal ions have diffused, it is possible to form a low-resistance metallic bridge between the anode A and the cathode K, so that the electrical resistance of the memory cell drops considerably.

To fabricate a memory cell of this type, materials such as for example GeₓSe₁₋ₓ, GeₓS₁₋ₓ WOx, Cu—S, Cu—Se or similar chalcogenide-containing compounds are generally used for the ion conductor. Typical reactive metal electrode materials are in this case Cu or in particular Ag, Na, Li, etc.

The present invention application is intended to present an integration approach for a 1T1R-CBRAM architecture which is distinguished in particular by the simplicity of its procedure. The individual memory cells are in this case not geometrically separated from one another, as in the active-in-via architecture, in which the active material is present only in contact holes, but rather share one cohesive layer of ion conductor material and active metal electrode. Nevertheless, each individual cell can be addressed individually via its associated select transistor.

For a CB memory concept of this type, hitherto only data on the fabrication and programming of individual cells in a vertical geometry or a coplanar geometry—which is unsuitable for high density memories—have been published. The objective for competitive, commercial use as a CBRAM must be very large scale integration of cells of this type to form an array using technology which can be controlled as simply as possible. A cross-point architecture and a 1TnR arrangement have been proposed for the arrangement of a large number of cells in a memory array. However, neither case describes an integration concept.

The present invention proposes an integration option allowing a CBRAM cell to be integrated in a CMOS process flow.

The array architecture described is distinguished in particular by an underlying simple procedure for fabrication of the individual cells.

The individual memory cells are in this case not geometrically separated from one another—as in the active-in-via architecture—but rather share cohesive layers of the ion conductor material, on the one hand, and an active metal electrode, on the other hand. Consequently, there is no need either for high resolution lithography for the upper electrode or for expensive CMP machines (CMP: chemical mechanical polishing) for the active layer. Since the structures to be etched have only uncritical dimensions, i.e., the entire cell area, for example on a mm scale—it is, if appropriate, also possible to use a wet etching step, so that there is no need for a special RIE tool.

Despite this simplified structure, however, each individual cell can be addressed individually via its associated select transistor, unambiguously and without any half-select difficulties, i.e., without crosstalk of programming pulses onto adjacent cells.

A core concept of the present invention is the use of both a common and unstructured active layer and of a common second electrode for a multiplicity of CBRAM cells in the memory cell field. In this case, the second electrode and the active material are patterned, with a noncritical resolution, only at a suitable location or suitable locations—e.g., at the edge of the cell field—for example wet-chemically or by a dry route using a mask with noncritical feature sizes, e.g., mid-UV, i.e., MUV at approximately 365 nm.

The integration plan is described in more detail in the appended figures. The CBRAM memory cell is placed, in a storage-element-over-BL cell architecture, onto what is known as the CC contact or node contact, which is connected via what is known as a CA contact to the respective select transistor in the silicon substrate.

In the first and even simpler of the two approaches shown, first of all the CC plugs, which consist, for example of tungsten W, are lithographically defined, etched, filled with tungsten W and planarized.

Then, the ion conductor material, e.g. GeₓSe₁₋ₓ or a similar suitable chalcogenide glass, is deposited on the planar surface of the ion conductor material. The planar deposition is particularly advantageous for sputter deposition, since in this case the composition of the chalcogenide compound can be controlled much more successfully than, for example, in narrow vias with an aggressive aspect ratio.

Then, the reactive electrode is deposited, e.g. once again by sputtering, followed by the second electrode. Then, the plate electrode is defined by uncritical lithography, e.g., at the edge of the cell field, and patterned dry or in particular also wet chemically.

In a slightly modified process sequence, it is advantageously also possible for the active material to be completely encapsulated by a diffusion barrier.

For this purpose, prior to the definition of the CC contacts, a diffusion-inhibiting material, such as for example SiN, is deposited in planar form and also etched following the contact lithography. Next—completely analogously to the method described above—the tungsten plugs are produced and the active layers and the plate electrode are deposited in planar form and patterned. Then, the active material together with the plate electrode can be passivated and protected against outdiffusion by simple deposition of a further SiN layer. This applies in particular to the etching flanks which are open at the edges of the cell field.

One significant aspect of the methods described, however, is that a multiplicity of cells are not geometrically separate from one another, but rather are continuously connected to one another in one cohesive active layer and are also electrically combined by a common top electrode, what is known as the plate PL.

Nevertheless, the cells can be electrically actuated in each case individually by means of their connection to the select transistor, since the active material between two adjacent contacts has only a negligible conductivity, in particular with a resistance of greater than approximately 10¹¹ Ohm.

When the cells are operating, the plateline can in the simplest case be kept at a constant potential level, e.g., in accordance with FIG. 3 for pulse actuation of the bit line BL and the word line WL, which in addition to the simple circuitry, also brings the benefit of the respective cells having minimal influence on one another.

FIG. 3 shows a schematic sequence comprising a write pulse, a read pulse, an erase pulse and another read pulse. Lower pulse heights are used for the reading, in order not to interfere with the state of the cell during reading.

The above and still further objects, features and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

FIGS. 1A, 1B illustrate a sectional side view of fundamental properties of solid electrolyte memory cells in accordance with an exemplary embodiment of the present invention.

FIG. 2 is a diagram illustrating a circuit arrangement, a semiconductor memory device, in which a memory cell array comprising a plurality of solid electrolyte memory cells in accordance with an exemplary embodiment of the present invention.

FIG. 3 shows two graphs illustrating the profile of the bit line voltage and the word line voltage, respectively, as a function of time.

FIG. 4 shows a sectional side view of the memory cell array in a semiconductor memory device in accordance with an exemplary embodiment of the present invention.

FIG. 5 shows a sectional side view of another memory cell array in a semiconductor memory device according in accordance with an exemplary embodiment of the present invention.

### DETAILED DESCRIPTION

In the text which follows, structurally and/or functionally similar or equivalent structures or method steps are denoted by the same reference designations. A detailed description of the structural elements or method steps is not repeated each time they occur.

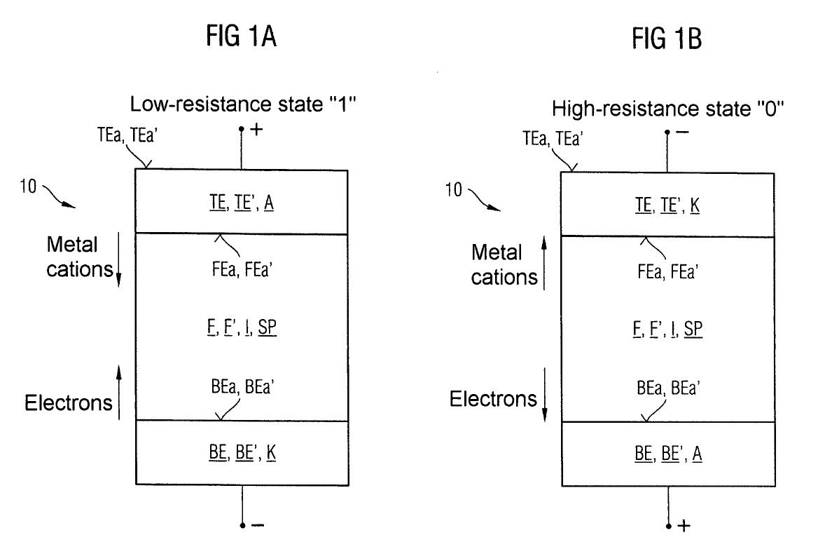

FIGS. 1A and 1B show a diagrammatic and sectional side view of a solid electrolyte memory cell 10 as used in the present concept according to the invention.

The solid electrolyte memory cell 10 shown in FIGS. 1A and 1B comprises a first (or lower) electrode device BE, which can also be referred to as the bottom electrode BE, a second (or upper) electrode device TE, which can also be referred to as the top electrode TE, and a solid electrolyte material region F of a solid electrolyte material provided between the two electrode devices as memory material region Sp.

According to the invention, the solid electrolyte material region F is designed in such a way as to be materially cohesive, e.g. in the form of a common material layer F′, for a plurality of solid electrolyte memory cells 10 in an array 1. The solid electrolyte material region F comprises on the one hand a base substance, which is also referred to as the ion conductor I, and an activating species, e.g., in the form of metal ions, provided therein. These metal ions may, for example, be monovalent silver cations which are provided in a corresponding chalcogenide material as ion conductor I, for example as silver-enriched precipitates.

FIG. 1A shows a memory cell 10 which is in a write state or is being operated in a write state. This is achieved by virtue of the fact that the first electrode BE is connected as cathode K and is therefore acted on by a negative electrical potential and that the second electrode TE is connected as anode A and is therefore acted on by a positive electrical potential. The result of this is that the metal ions provided as activating species diffuse into the solid electrolyte material region F or ion conductor I, where they are distributed and thereby, by interacting with electrons which diffuse in from the cathode, form a conductive bridge.

In this way, a relatively low-resistance state with an increased total conductivity or a reduced total resistance is formed, and this can be identified as the low-resistance state of the solid electrolyte material region F as memory material region Sp with a first information state, e.g. a logic 1 (“1”).

FIG. 1B illustrates an erase state for the solid electrolyte memory cell 10, which is achieved by virtue of the fact that the first electrode BE is connected as anode A and is therefore at a positive electrical potential, and that the second electrode TE is connected as cathode K and is therefore at a negative electrical potential. The result of this is that the activating species in the form of metal ions are displaced out of the ion conductor I via the cathode K, i.e., in this case via the second electrode TE, and the electrons are displaced out of the ion conductor I via the anode A, i.e., in this case via the first electrode BE.

This results in a relatively high-resistance state with an increased total resistance and a reduced total conductivity, which can be identified by a second information state, e.g., a logic zero (“0”).

Furthermore, it can be seen from FIGS. 1A and 1B that the solid electrolyte memory cell 10 in this preferred embodiment is vertically oriented. This means that the sequence of first electrode device BE, ion conductor I and second electrode device TE is a vertical sequence of the corresponding material layers.

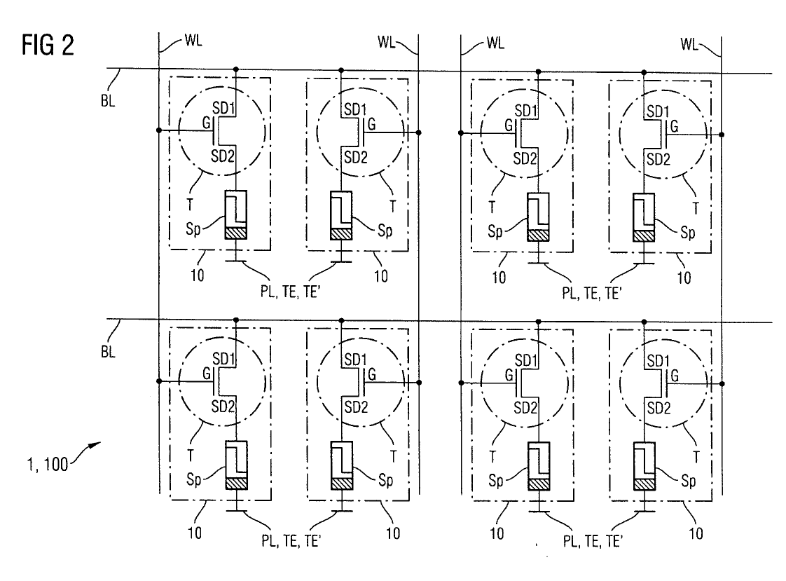

FIG. 2 shows, in diagrammatic form by means of a circuit arrangement, a semiconductor memory device 100 according to the invention, in which a memory cell array 1 according to the invention, comprising a plurality of solid electrolyte memory cells 10.

Each of the solid electrolyte memory cells 10 has a corresponding memory material region Sp, which can be accessed for writing, reading or erasing purposes by means of a select transistor T via the electrodes BE and TE. Each of the select transistors T is connected via its gate terminal G to a word line WL and via a source/drain region SD remote from the memory material region Sp to a corresponding bit line BL. The source/drain region SD of the select transistor T which in each case faces the memory material region Sp then accesses the actual memory material region Sp via the first electrode device BE.

The memory material regions Sp of the individual solid electrolyte memory cells 10 according to the invention are formed by one common material layer F′, which according to the invention is adjoined by one common material layer TE′ for the second electrode devices TE in the form of a common plateline PL or plateline plate PL.

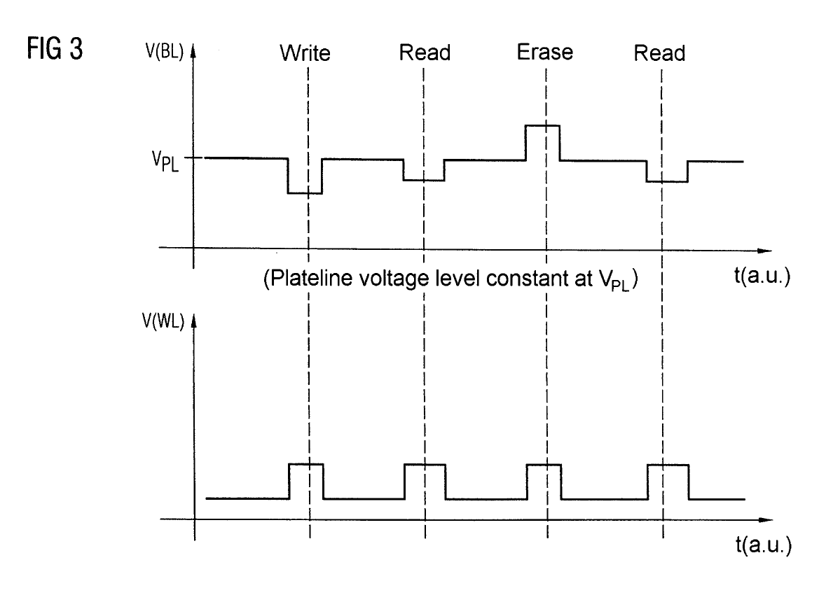

FIG. 3 shows, in the form of two graphs illustrating the profile of the bit line voltage or the word line voltage as a function of time, a corresponding operating plan for a memory cell array 1 according to the invention, in which defined solid electrolyte memory cells 10 of the array 1 are to be driven via the corresponding select transistors T.

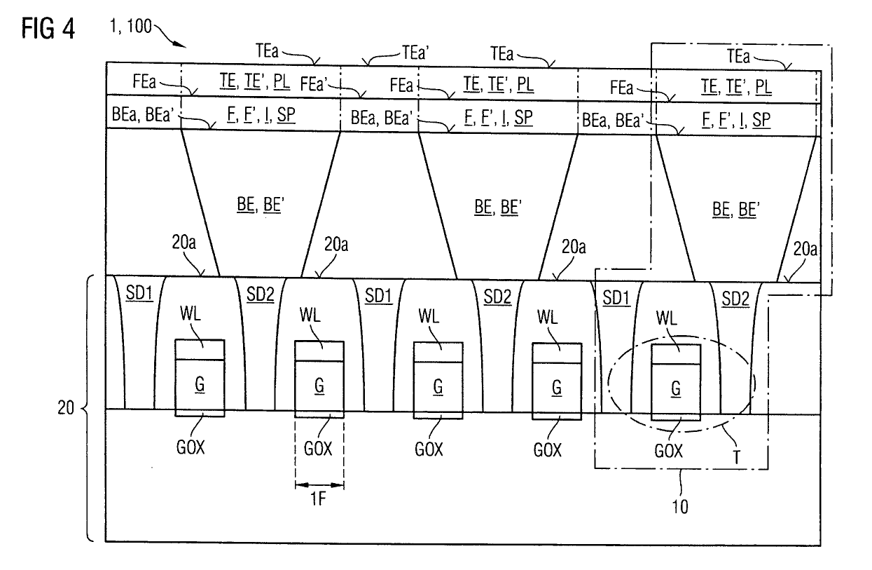

FIG. 4 shows a sectional side view of a first preferred embodiment of the memory cell array 1 according to the invention, representing the concept shown in FIGS. 1A and 1B.

The lower part of the illustration presented in FIG. 4 reveals access transistors T which are formed in a substrate 20 with a surface region 20A and the gate arrangements G of which are connected to the word lines WL of the memory cell array 1. Also provided are first and second source/drain regions SD1, SD2, the first source/drain region SD1 being connected to a bit line BL (not shown here), which runs offset in the plane of the drawing, and the second source/drain region SD2 in each case being connected to a first electrode device BE in the form of a plug or CC plug. The first and second source/drain regions SD1 and SD2 are also formed as plugs.

The first electrode device BE is in each case adjoined by a continuous layer F′ of an ion conductor material I with a correspondingly activating species in continuous form, with the result that, by interacting with the first electrode devices BE, the respective local solid electrolyte material regions F result as memory material regions Sp of the individual solid electrolyte memory cells 10. The plateline PL, as a common layer TE′ for the second electrode devices TE of all of the or the array 1 of the solid electrolyte memory cells 10, rests directly on the surface Fa′ of the layer F′ of the ion conductor material I.

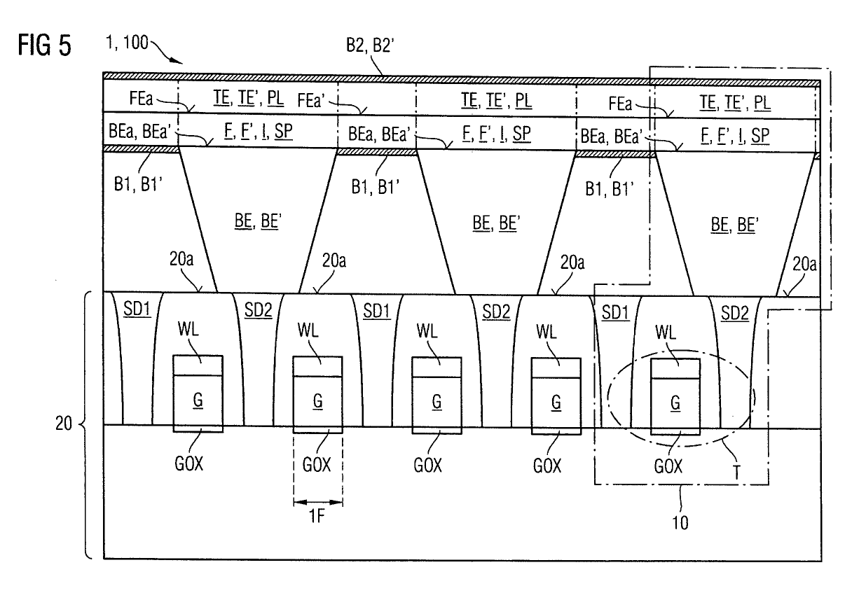

The embodiment shown in FIG. 5 approximately corresponds to the embodiment shown in FIG. 4, except that in addition what are known as silicon nitride liners are provided, as barrier regions B1 and B2 of common continuous layers B1′ and B2′, below the common layer F′ for the solid electrolyte material regions F and above the common layer TE′ for the second electrode devices TE of the solid electrolyte memory cells 10, which barrier regions encapsulate the solid electrolyte memory cells 10 of the array 1 by inhibiting diffusion.

Having described preferred embodiments of new and improved semiconductor memory device, memory cell array, and method for making the same, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

### List of Designations

1 Memory cell array according to the invention
10 Solid electrolyte memory cell
20 Substrate, semiconductor material region
20a Surface region
100 Semiconductor memory device according to the invention
A Anode
B1 First barrier region
B2 Second barrier region
B1′ Common layer for first barrier region B1
B2′ Common layer for second barrier region B2
BE First, lower or bottom electrode device
BEa Surface region
BE′ Material for first, lower or bottom electrode device BE
BEa′ Surface region
F Solid electrolyte material region
Fa Surface region
F′ Common layer for solid electrolyte material region F
Fa′ Surface region
G Gate electrode, gate, gate region
GOX Gate insulation region
I Ion conductor, ion conductor material
K Cathode
PL Plateline
PL′Common layer for plateline PL
Sp Memory material region
TE Second, upper or top electrode device
TEa Surface region
TE′ Common layer for first electrode device TE
TEa′ Surface region

1. A memory cell array, comprising:
a plurality of solid electrolyte memory cells, wherein individual ones of the solid electrolyte memory cells comprise: a first electrode device, a second electrode device, and an activated or activatable solid electrolyte material region between the first and second electrode devices, wherein the solid electrolyte material regions of the plurality of solid electrolyte memory cells are materially cohesive and the second electrode devices of the plurality of solid electrolyte memory cells are materially cohesive.

2. The memory cell array according to claim 1, wherein the solid electrolyte material regions of the plurality of solid electrolyte memory cells are formed as one common material layer.

3. The memory cell array according to claim 1, wherein the second electrode devices of the plurality of solid electrolyte memory cells are formed as one common material layer.

4. The memory cell array according to claim 1, wherein the first electrode device, the solid electrolyte material region, and the second electrode device of individual ones of the solid electrolyte memory cells are arranged as a vertically running sequence of corresponding material regions or material layers.

5. The memory cell array according to claim 1, wherein the first electrode device comprises an anode or a cathode.

6. The memory cell array according to claim 1, wherein the second electrode device comprises a cathode or an anode.

7. The memory cell array according to claim 1, wherein the second electrode devices of respective solid electrolyte memory cells are formed in one common vertical plane.

8. The memory cell array according to claim 1, wherein the solid electrolyte material regions of respective solid electrolyte memory cells are formed in one common vertical plane.

9. The memory cell array according to claim 1, wherein the first electrode devices of respective solid electrolyte memory cells are formed in one common vertical plane.

10. The memory cell array according to claim 1, wherein the first electrode device comprises at least one of the following materials: polysilicon, tungsten, titanium, tantalum, silver, copper, and aluminum and at least one of the following electrically conductive materials: nitrides, oxides, alloys, and compounds thereof.

11. The memory cell array according to claim 1, wherein the second electrode device comprises at least one of the following materials: polysilicon, tungsten, titanium, tantalum, silver, silver chalcogenides, copper, and aluminum and at least one of the following electrically conductive materials: nitrides, oxides, alloys, and compounds thereof.

12. The memory cell array according to claim 1, wherein the solid electrolyte material region comprises at least one of the following materials: WOx, GeSe, GeS, SiSe, SiS, SiGe, SeS, Si—Se—S, Si—Ge—Se, Si—Ge—S, Ge—Se—S, Si—Ge—Se—S, and other chalcogenide materials.

13. The memory cell array according to claim 1, wherein the memory cell array is formed on or in a semiconductor material region as a substrate or on or in a surface region thereof.

14. The memory cell array according to claim 1, wherein each solid electrolyte memory cell comprises an individual selection transistor.

15. The memory cell array according to claim 1, wherein the solid electrolyte material region is embedded by diffusion barriers.

16. The memory cell array according to claim 15, wherein respective diffusion barriers for all the solid electrolyte memory cells are formed as materially cohesive regions and as common layers.

17. A semiconductor memory device, comprising:
the plurality of solid electrolyte memory cells according to claim 1; and
logic circuits and switching elements for controlling the solid electrolyte memory cells.

18. A method for fabricating a memory cell array comprising a plurality of solid electrolyte memory cells, the method comprising:
forming each solid electrolyte memory cell with a first electrode device, a second electrode device, and an activated or activatable solid electrolyte material region between the first and second electrode devices;
forming the solid electrolyte material regions of the plurality of solid electrolyte memory cells to be materially cohesive; and
forming the second electrode devices of the plurality of solid electrolyte memory cells to be materially cohesive.

19. The method according to claim 18, wherein the solid electrolyte material regions of the plurality of solid electrolyte memory cells are formed as one common material layer.

20. The method according to claim 18, wherein the second electrode devices of the plurality of solid electrolyte memory cells are formed as one common material layer.

21. The method according to claim 18, wherein the first electrode device, the solid electrolyte material region, and the second electrode device are formed as a vertically running sequence of corresponding material regions or material layers.

22. The method according to claim 18, wherein the first electrode device comprises an anode or a cathode.

23. The method according to claim 18, wherein the second electrode device comprises a cathode or an anode.

24. The method according to claim 18, wherein the second electrode devices of respective solid electrolyte memory cells are formed in one common vertical plane.

25. The method according to claim 18, wherein the solid electrolyte material regions of respective solid electrolyte memory cells are formed in one common vertical plane.

26. The method according to claim 18, wherein the first electrode devices of respective solid electrolyte memory cells are formed in one common vertical plane.

27. The method according to claim 18, wherein the first electrode device comprises at least one of the following materials: polysilicon, tungsten, titanium, tantalum, silver, copper, and aluminum and at least one of the following electrically conductive materials: nitrides, oxides, alloys, and compounds thereof.

28. The method according to claim 18, wherein the second electrode device comprises at least one of the following materials: polysilicon, tungsten, titanium, tantalum, silver, silver chalcogenides, copper, and aluminum and comprises at least one of the following electrically conductive materials: nitrides, oxides, alloys, and compounds thereof.

29. The method according to claim 18, wherein the solid electrolyte material region comprises at least one of the following materials: WOx, GeSe, GeS, SiSe, SiS, SiGe, SeS, Si—Se—S, Si—Ge—Se, Si—Ge—S, Ge—Se—S, Si—Ge—Se—S, and other chalcogenide materials.

30. The method according to claim 18, wherein the memory cell array is formed on or in a semiconductor material region as a substrate or on or in a surface region thereof.

31. The method according to claim 18, wherein each solid electrolyte memory cell comprises an individual selection transistor.

32. The method according to claim 18, wherein the solid electrolyte material region is embedded by diffusion barriers.

33. The method according to claim 32, wherein respective diffusion barriers for all the solid electrolyte memory cells are formed as materially cohesive regions and as common layers.
